(19) United States
(12) Patent Application Publication
(10) Pub. No.: US 2021/0313960 A1
(43) Pub. Date: Oct. 7, 2021

(54) VIBRATOR ELEMENT

(71) Applicant: SEIKO EPSON CORPORATION, Tokyo (JP)

(72) Inventors: Kenichi Oto, Suwa-shi (JP); Kenichi Kurokawa, Suwa-shi (JP); Yukio Kitahara, Chino-shi (JP)

(21) Appl. No.: 17/220,186

(22) Filed: Apr. 1, 2021

(30) Foreign Application Priority Data
Apr. 3, 2020 (JP) 2020-067288

(51) Int. Cl. H03H 9/24; H03H 9/02; H03H 9/05

(52) U.S. Cl. CPC H03H 9/2489; H03H 9/0595; H03H 9/02448; H03H 9/02259

(57) ABSTRACT

A vibrator element includes: a base; an arm that is made of silicon and continuous with the base; a silicon dioxide layer arranged on the arm and a continuous portion in which the arm and the base are continuous; a zirconium dioxide layer arranged on the silicon dioxide layer at least in the continuous portion; a first electrode arranged on the zirconium dioxide layer; a piezoelectric layer arranged on the first electrode; and a second electrode arranged on the piezoelectric layer.

The present application is based on, and claims priority from JP Application Serial Number 2020-067288, filed Apr. 3, 2020, the disclosure of which is hereby incorporated by reference herein in its entirety.

### BACKGROUND

### 1. Technical Field

The present disclosure relates to a vibrator element.

### 2. Related Art

In the related art, there has been a vibrator having a structure of micro electromechanical systems (MEMS) in which an excitation section including a piezoelectric thin film is formed on a silicon semiconductor layer. For example, JP-A-2018-101829 cited below discloses a vibrator having a structure provided with an excitation section in which a first silicon oxide layer having a high density and a second silicon oxide layer having a low density are stacked on a silicon layer serving as a vibrating arm, and a first electrode, a piezoelectric layer, and a second electrode are stacked on the second silicon oxide layer in this order. The first silicon oxide layer and the second silicon oxide layer are provided to reduce a temperature coefficient of frequency (TCF) of the vibrator. Compared with a case of one silicon oxide layer, a quality variation of the silicon oxide layers as a whole can be prevented, and a variation of the temperature coefficient of frequency can be reduced.

However, in the vibrator described in JP-A-2018-101829, stress is generated concentratedly between the vibrating arm and a base connected to the vibrating arm upon excitation of the vibrator, and thus there is a possibility that cracks occur on the silicon oxide layers when the stress is applied repeatedly, which causes breakage of the electrodes provided above.

### SUMMARY

A vibrator element includes: a base; an arm that is made of silicon and continuous with the base; a silicon dioxide layer arranged on the arm and a continuous portion in which the arm and the base are continuous; a zirconium dioxide layer arranged on the silicon dioxide layer at least in the continuous portion; a first electrode arranged on the zirconium dioxide layer; a piezoelectric layer arranged on the first electrode; and a second electrode arranged on the piezoelectric layer.

### BRIEF DESCRIPTION OF THE DRAWINGS

FIG. 1 is a schematic plan view showing a configuration of a vibrator element according to a first embodiment.

FIG. 2 is a schematic cross-sectional view taken along a line A-A of FIG. 1.

FIG. 3 is a schematic cross-sectional view taken along a line B-B of FIG. 1.

FIG. 4 is a diagram comparing characteristics of each temperature coefficient adjusting film.

FIG. 5 is a schematic plan view showing a manufacturing process of the vibrator element according to the first embodiment.

FIG. 6 is a schematic cross-sectional view corresponding to a position of a line C-C in FIG. 5 showing the manufacturing process of the vibrator element according to the first embodiment.

FIG. 7 is a schematic cross-sectional view corresponding to the position of the line C-C in FIG. 5 showing the manufacturing process of the vibrator element according to the first embodiment.

FIG. 8 is a schematic cross-sectional view corresponding to the position of the line C-C in FIG. 5 showing the manufacturing process of the vibrator element according to the first embodiment.

FIG. 9 is a schematic plan view showing the manufacturing process of the vibrator element according to the first embodiment.

FIG. 10 is a schematic cross-sectional view corresponding to the position of the line C-C in FIG. 5 showing the manufacturing process of the vibrator element according to the first embodiment.

FIG. 11 is a schematic cross-sectional view corresponding to the position of the line C-C in FIG. 5 showing the manufacturing process of the vibrator element according to the first embodiment.

FIG. 12 is a schematic plan view showing the manufacturing process of the vibrator element according to the first embodiment.

FIG. 13 is a schematic cross-sectional view corresponding to the position of the line C-C in FIG. 5 showing the manufacturing process of the vibrator element according to the first embodiment.

FIG. 14 is a schematic cross-sectional view corresponding to the position of the line C-C in FIG. 5 showing the manufacturing process of the vibrator element according to the first embodiment.

FIG. 15 is a schematic plan view showing the manufacturing process of the vibrator element according to the first embodiment.

FIG. 16 is a schematic cross-sectional view corresponding to the position of the line C-C in FIG. 5 showing the manufacturing process of the vibrator element according to the first embodiment.

FIG. 17 is a schematic cross-sectional view showing a configuration of a vibrator element according to a second embodiment.

FIG. 18 is a schematic plan view showing a configuration of a vibrator element according to a third embodiment.

FIG. 19 is a schematic cross-sectional view taken along a line D-D of FIG. 18.

FIG. 20 is a schematic cross-sectional view taken along a line E-E of FIG. 18.

### DESCRIPTION OF EXEMPLARY EMBODIMENTS

### 1. First Embodiment

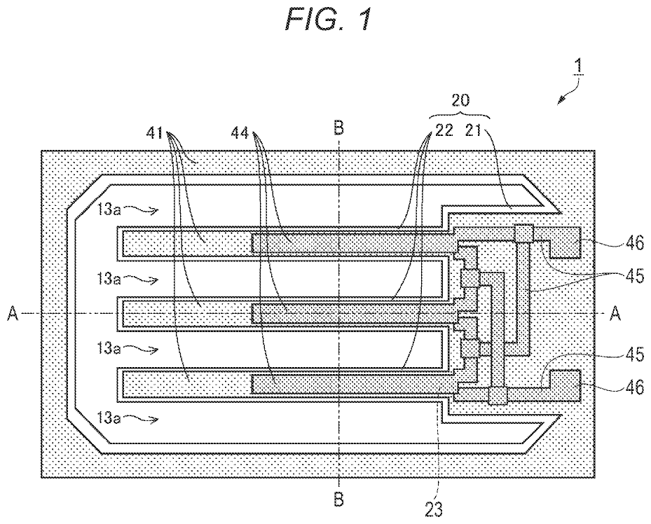

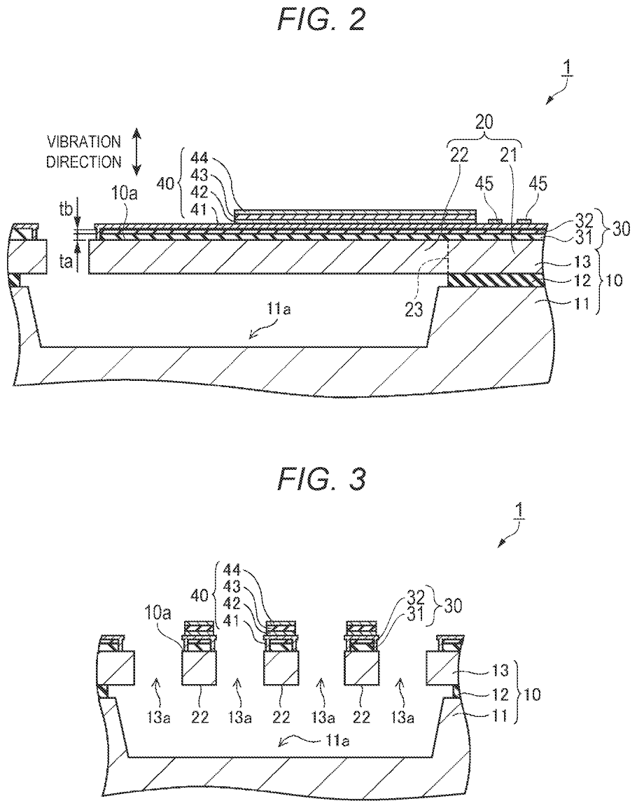

First, a vibration piece 1 according to a first embodiment will be described with reference to FIGS. 1, 2, and 3.

The vibrator element 1 according to the present embodiment can be manufactured by processing a silicon on insulator (SOI) substrate 10. The SOI substrate 10 is a substrate in which a silicon substrate 11, a buried oxide film (BOX: buried oxide) 12, and a surface silicon layer 13 are stacked in this order. For example, the silicon substrate 11 and the surface silicon layer 13 are made of single crystal silicon (Si), and the buried oxide film 12 is made of silicon dioxide (SiO₂) or the like. In the present embodiment, the surface silicon layer 13 corresponds to a base material constituting a base 21 and arms 22.

As shown in FIGS. 1, 2, and 3, the vibrator element 1 includes the silicon substrate 11, the buried oxide film 12 arranged in a partial region of the silicon substrate 11, a vibrating body 20 made of silicon of the surface silicon layer 13, a temperature coefficient adjusting film 30 in which a silicon dioxide layer 31 and a zirconium dioxide layer 32, which are arranged in a predetermined region of the vibrating body 20, are stacked, and a piezoelectric drive unit 40 that is arranged on an opposite side of the temperature coefficient adjusting film 30 from the vibrating body 20 and that covers at least a part of the temperature coefficient adjusting film 30.

The vibrating body 20 includes the base 21 supported by the buried oxide film 12, and the arms 22 separated from surrounding silicon other than the base 21 by grooves 13a on a region where the buried oxide film 12 is removed. That is, the vibrating body 20 includes the base 21 and the arms 22 made of the silicon continuous with the base 21. In the example shown in FIGS. 1 to 3, the vibrating body 20 includes three arms 22. A cavity 11a is formed in the silicon substrate 11 at a position facing the arms 22.

The temperature coefficient adjusting film 30 is made of the silicon dioxide (SiO₂) layer 31 and the zirconium dioxide (ZrO₂) layer 32, and the silicon dioxide layer 31 and the zirconium dioxide layer 32 are stacked in this order from a surface silicon layer 13 side. That is, the silicon dioxide layer 31 is arranged on a main surface 10a of the surface silicon layer 13 at an opposite side from a surface on which the buried oxide film 12 is arranged, and the zirconium dioxide layer 32 is arranged on a side of the silicon dioxide layer 31 at an opposite side from the surface silicon layer 13. In the present embodiment, the temperature coefficient adjusting film 30 is arranged in a predetermined region of the vibrating body 20, which includes the arms 22, the base 21, and a continuous portion 23 in which the arms 22 and the base 21 are continuous. The arms 22 vibrate in a direction intersecting a plane passing through the three arms 22. Therefore, the main surface 10a of the surface silicon layer 13 is a surface that intersects a vibration direction of the arms 22.

The silicon dioxide layer 31 is formed by a thermal oxidation method of thermally oxidizing the surface silicon layer 13 or a chemical vapor deposition (CVD) method, and the zirconium dioxide layer 32 is formed by a sputtering method or a sol-gel method.

The piezoelectric drive unit 40 includes a polysilicon film 41, first electrodes 42, a piezoelectric layer 43, second electrodes 44, and a plurality of wirings 45. The polysilicon film 41 is made of polysilicon that is not doped with impurities, and may be made of amorphous silicon, for example. In the present embodiment, the polysilicon film 41 and the vibrating body 20 cover the temperature coefficient adjusting film 30. Accordingly, the polysilicon film 41 can protect the temperature coefficient adjusting film 30 from etching of the silicon dioxide layer around the piezoelectric drive unit 40.

Each first electrode 42 and second electrode 44 are arranged so as to sandwich the piezoelectric layer 43. That is, on an opposite side of the zirconium dioxide layer 32 from the silicon dioxide layer 31, the first electrode 42 arranged with the polysilicon film 41 interposed therebetween, the piezoelectric layer 43 arranged on an opposite side of the first electrode 42 from the zirconium dioxide layer 32, and the second electrodes 44 arranged on an opposite side of the piezoelectric layer 43 from the first electrodes 42 are stacked in this order. In the examples shown in FIGS. 1 to 3, a total of three sets of the first electrode 42, the piezoelectric layer 43, and the second electrode 44 are provided correspondingly for each of the three arms 22.

The plurality of wirings 45 are electrically coupled to the first electrodes 42 and the second electrodes 44 so as to vibrate adjacent arms 22 in opposite phases. Further, the plurality of wirings 45 are electrically coupled to electrode pads 46, and by applying a voltage from the outside between the two electrode pads 46, the adjacent arms 22 can be vibrated in the opposite phases.

As a material constituting these elements, for example, the piezoelectric layer 43 is made of aluminum nitride (AlN) or the like, the first electrodes 42 and the second electrodes 44 are made of titanium nitride (TiN) or the like, and the plurality of wirings 45 and the electrode pads 46 are made of aluminum (Al), copper (Cu) or the like.

When the voltage is applied between the first electrodes 42 and the second electrodes 44 via the two electrode pads 46, the piezoelectric layer 43 expands and contracts and the arms 22 vibrate. The vibration is greatly excited at an inherent resonance frequency, which minimizes an impedance. As a result, an oscillator using the vibration piece 1 oscillates at an oscillation frequency mainly determined by the resonance frequency of the arms 22.

Next, the temperature coefficient adjusting film 30 will be described in detail.

The temperature coefficient adjusting film 30 is provided to correct a temperature coefficient of frequency of the resonance frequency of the arms 22. Silicon has a temperature coefficient of frequency in which the resonance frequency decreases as a temperature rises, while silicon dioxide (SiO₂) and zirconium dioxide (ZrO₂) have a temperature coefficient of frequency in which the resonance frequency increases as the temperature rises. Therefore, by arranging the temperature coefficient adjusting film 30 which is silicon dioxide or zirconium dioxide on the arms 22 of the vibrating body 20 made of silicon, a temperature coefficient of frequency of a resonance frequency of a composite constituted by the arms 22 of the vibrating body 20 and the temperature coefficient adjusting film 30 can be brought close to flat. Specifically, for example, an amount of change of about ±3,000 ppm in the resonance frequency of the vibrating body 20 in a temperature range of −25° C. to +75° C. can be flattened to about ±200 ppm to about ±500 ppm by forming the temperature coefficient adjusting film 30.

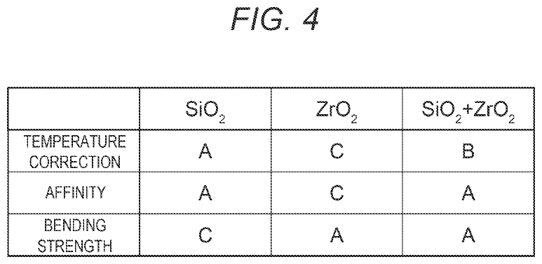

Further, as the temperature coefficient adjusting film 30 for correcting the temperature coefficient of frequency of the resonance frequency of the vibrating body 20, silicon dioxide, zirconium dioxide, a stacked-layer film of silicon dioxide and zirconium dioxide, or the like is used. As various characteristics of each temperature coefficient adjusting film 30, “temperature correction” indicating a magnitude of an correction effect of the temperature coefficient of frequency of the vibrating body 20, “affinity” indicating an adhesion to silicon which is the vibrating body 20, and “bending strength” indicating a mechanical strength to the vibration direction are compared in FIG. 4. Here, “A” in FIG. 4 means that the characteristics are very good, “B” means that the characteristics are good, and “C” means that the characteristics are poor. Further, in the “temperature correction”, “good” means that a coefficient that corrects the temperature coefficient of frequency is large, and “poor” means that the coefficient that corrects the temperature coefficient of frequency is small.

From FIG. 4, silicon dioxide has a large correction effect on the temperature coefficient of frequency and is excellent in the adhesion to silicon, but has a weak bending strength in the vibration direction. Further, zirconium dioxide has a small correction effect on the temperature coefficient of frequency and is inferior in the adhesion to the silicon, but has a strong bending strength in the vibration direction. Further, as compared to a silicon dioxide single layer, a film in which silicon dioxide and zirconium dioxide are stacked in this order on the vibrating body 20 is slightly inferior in the correction effect of the temperature coefficient of frequency, but is excellent in the adhesion to the silicon or the bending strength in the vibration direction.

Therefore, in the present embodiment, the temperature coefficient of frequency of the resonance frequency of the vibrating body 20 can be corrected by forming the temperature coefficient adjusting film 30 in which the silicon dioxide layer 31 and the zirconium dioxide layer 32 are stacked in this order on the vibrating body 20. Further, since the zirconium dioxide layer 32 having the strong bending strength in the vibration direction is arranged, it is possible to reduce a possibility that due to the vibration of the vibrating body 20, a stress is concentrated on the continuous portion 23 in which the arms 22 and the base 21 are continuous, and cracks occur on the temperature coefficient adjusting film 30 due to repeatedly applied stress, which causes breakage of the first electrode 42, the second electrode 44, or the like provided on an upper layer of the temperature coefficient adjusting film 30.

Further, in the temperature coefficient adjusting film 30 in which the silicon dioxide layer 31 and the zirconium dioxide layer 32 are stacked, a thickness ta of the silicon dioxide layer 31 is larger than a thickness tb of the zirconium dioxide layer 32. The reason is that, as shown in FIG. 4, zirconium dioxide has a smaller correction effect on the temperature coefficient of frequency of the vibrating body 20 than silicon dioxide, and therefore, in order to make the correction effect of zirconium dioxide equivalent to that of silicon dioxide, a layer thickness of zirconium dioxide needs to be larger than a layer thickness of silicon dioxide. Therefore, by making the thickness ta of the silicon dioxide layer 31 larger than the thickness tb of the zirconium dioxide layer 32, a thickness of the temperature coefficient adjusting film 30 made of two layers including the silicon dioxide layer 31 and the zirconium dioxide layer 32 can be reduced compared with a case where the thickness to of the silicon dioxide layer 31 is thinner than the thickness tb of the zirconium dioxide layer 32.

The thickness tb of the zirconium dioxide layer 32 is preferably 0.4 μm or more and 1.0 μm or less. When the thickness tb of the zirconium dioxide layer 32 is less than 0.4 μm, the bending strength in the vibration direction becomes weak, and cracks are likely to occur on the temperature coefficient adjusting film 30 due to the stress caused by the vibration of the vibrating body 20. On the contrary, when the thickness tb of the zirconium dioxide layer 32 is larger than 1.0 μm, since a film forming time is long, productivity is reduced, and since the bending strength in the vibration direction becomes too strong, the vibrating body 20 is difficult to vibrate. That is, the impedance (CI: crystal impedance) of the vibrator element 1 becomes large, and it is difficult for an oscillation circuit to oscillate.

In the present embodiment, a tripod-shaped vibrator element 1 including the three arms 22 is described as an example, but the number of the plurality of arms 22 extending from the base 21 is not limited.

As described above, according to the vibrator element 1 provided with the temperature coefficient adjusting film 30 according to the present embodiment, the temperature coefficient adjusting film 30 in which the silicon dioxide layer 31 and the zirconium dioxide layer 32 are stacked on the surface silicon layer 13 is formed. Therefore, the temperature coefficient of frequency of the vibrator element 1 can be corrected by the temperature coefficient adjusting film 30 having a characteristic opposite to the temperature coefficient of frequency of the resonance frequency of the vibrating body 20. Further, since the zirconium dioxide layer 32 having the strong bending strength in the vibration direction is arranged, it is possible to reduce the possibility that due to the vibration of the vibrating body 20, the stress is concentrated on the continuous portion 23 in which the arms 22 and the base 21 are continuous, cracks occur on the temperature coefficient adjusting film 30 due to repeatedly applied stress, which causes breakage of the first electrode 42, the second electrode 44, or the like provided on the upper layer of the temperature coefficient adjusting film 30. Therefore, a vibrator element 1 that is excellent in the temperature coefficient of frequency and reliability can be obtained.

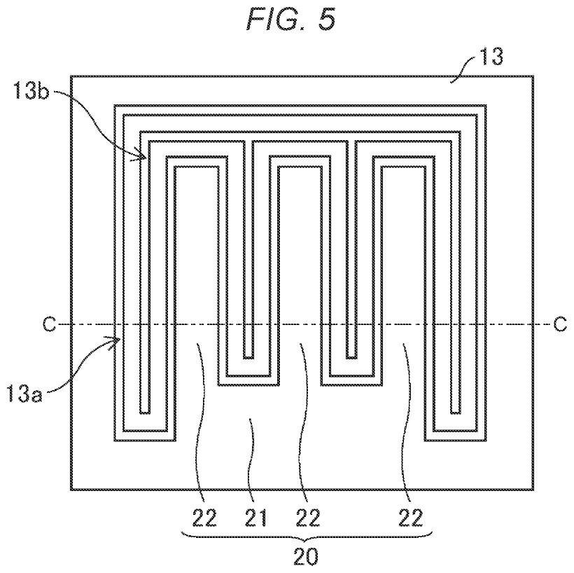

Next, a manufacturing process of the vibrator element 1 according to the present embodiment will be described with reference to FIGS. 5 to 16.

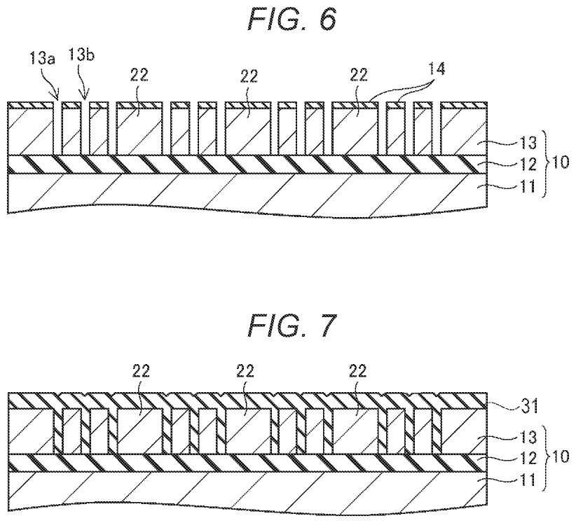

First, as a preparatory process, as shown in FIGS. 5 and 6, the SOI substrate 10 in which the silicon substrate 11, the buried oxide film 12, and the surface silicon layer 13 are stacked in this order is prepared. Alternatively, the SOI substrate 10 may be produced by forming the buried oxide film 12 on the silicon substrate 11 and forming the surface silicon layer 13 on the buried oxide film 12.

Next, in a first process, as shown in FIG. 5, the grooves 13a are formed in the surface silicon layer 13 of the SOI substrate 10 to separate a region serving as the arms 22 of the vibrating body 20 from the surrounding silicon other than a region serving as the base 21 of the vibrating body 20. At that time, a slit 13b may be formed in the region separated from the arms 22 of the vibrating body 20 by the grooves 13a of the surface silicon layer 13 of the SOI substrate 10. Accordingly, subsequent release etching of the silicon surrounding the arms 22 can be facilitated.

As for formation of the grooves 13a, by applying a photoresist 14 on the surface silicon layer 13, forming a mask pattern by a photolithography method, and etching the surface silicon layer 13 using the photoresist 14 as a mask, as shown in FIG. 6, the grooves 13a are formed on the surface silicon layer 13 to separate the region serving as the arms 22 of the vibrating body 20 from the surrounding silicon other than the region serving as the base 21 of the vibrating body 20. The grooves 13a may be formed by forming the silicon dioxide layer by thermally oxidizing a surface of the surface silicon layer 13 of the SOI substrate 10, forming the mask made of the silicon dioxide layer using the photolithography method, and etching the surface silicon layer 13.

In a second process, as shown in FIG. 7, the silicon dioxide layer 31 to be a part of the temperature coefficient adjusting film 30 is formed on an upper surface of the surface silicon layer 13 and side walls in the grooves 13a by the thermal oxidation method of thermally oxidizing the surface silicon layer 13 of the SOI substrate 10 or the CVD method.

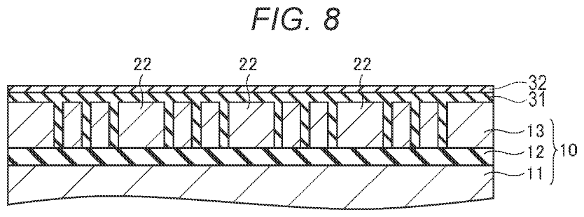

Next, in a third process, as shown in FIG. 8, the zirconium dioxide layer 32 to be a part of the temperature coefficient adjusting film 30 is formed on the silicon dioxide layer 31 by the sputtering method or the sol-gel method.

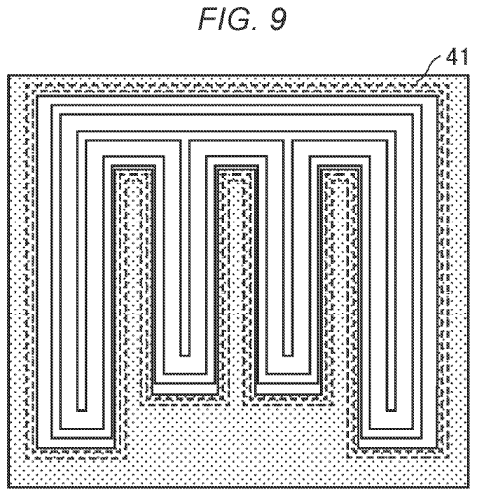

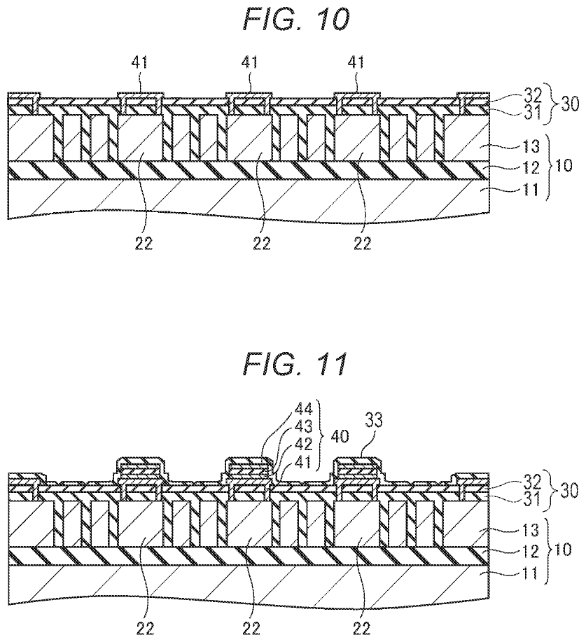

In a fourth process, by applying the photoresist on the zirconium dioxide layer 32, forming the mask pattern by the photolithography method, and etching the zirconium dioxide layer 32 and the silicon dioxide layer 31 using the photoresist as the mask, grooves reaching the vibrating body 20 are formed. After that, the polysilicon film 41 that covers the upper surface of the zirconium dioxide layer 32 and the side wall of the grooves of the silicon dioxide layer 31 is formed by the CVD method or the sputtering method, and by the photolithography method, as shown in FIGS. 9 and 10, the polysilicon film 41 is formed on the predetermined region of the vibrating body 20 including the arms 22.

In a fifth process, the first electrodes 42, the piezoelectric layer 43, and the second electrodes 44 are formed in this order on the polysilicon film 41 formed in the predetermined region of the vibrating body 20 by the photolithography method. The polysilicon film 41, the first electrodes 42, the piezoelectric layer 43, and the second electrodes 44 constitute the piezoelectric drive unit 40. After that, as shown in FIG. 11, a silicon dioxide layer 33 is formed on the SOI substrate 10 on which the piezoelectric drive unit 40 is formed by the CVD method or the sputtering method. The silicon dioxide layers 31 and 33 protect the arms 22 and the piezoelectric drive unit 40 from the subsequent release etching of the silicon surrounding the arms 22.

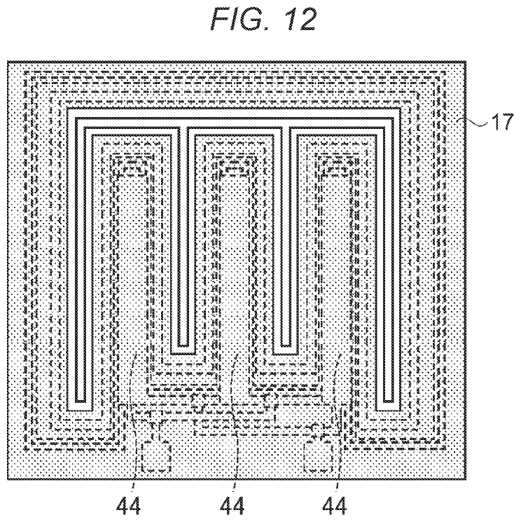

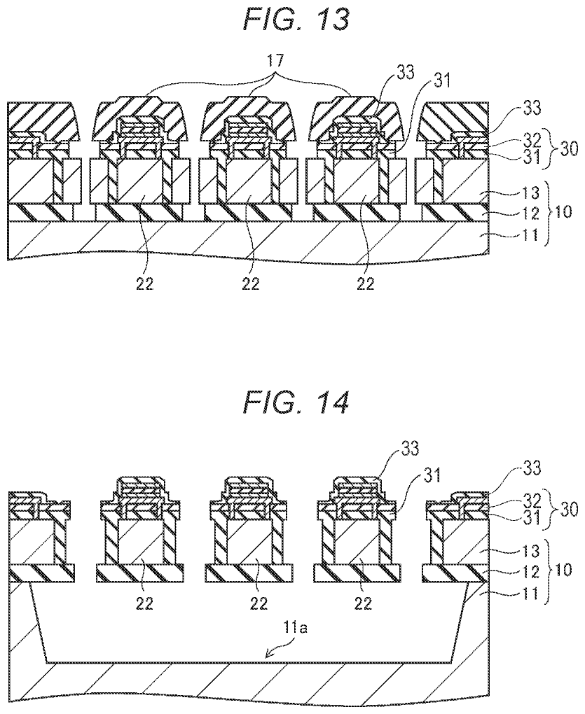

In a sixth process, as shown in FIGS. 12 and 13, a photoresist 17 is applied on the silicon dioxide layer 33, the mask pattern is formed by the photolithography method, and the silicon dioxide layer 33, the zirconium dioxide layer 32, and the silicon dioxide layer 31 are etched in this order using the photoresist 17 as the mask. Accordingly, openings having a depth that reach the silicon substrate 11 in a shape that surrounds the arms 22 are formed while remaining the silicon dioxide layer 31, the zirconium dioxide layer 32, and the silicon dioxide layer 33 that protect the arms 22 and the piezoelectric drive unit 40.

At that time, by providing the photoresist 17 including the openings that maintain a predetermined distance from the arms 22, when the silicon around the arms 22 is etched, the silicon dioxide layer 31, the zirconium dioxide layer 32, and the silicon dioxide layer 33 that protect the arms 22 and the piezoelectric drive unit 40 can be remained. When the slit 13b is formed on the surface silicon layer 13, since the openings reach the buried oxide film 12, the buried oxide film 12 of the SOI substrate 10 can be etched together with the silicon dioxide layer 31, the zirconium dioxide layer 32, and the silicon dioxide layer 33.

In a seventh process, as shown in FIG. 14, after the photoresist 17 is peeled off, the silicon surrounding the arms 22 is release-etched through the openings of the silicon dioxide layer 31, the zirconium dioxide layer 32, and the silicon dioxide layer 33. At that time, a part of the silicon of the silicon substrate 11 is etched to form the cavity 11a in the silicon substrate 11 below the arms 22. In the seventh process, wet etching is performed, and as an etching solution, for example, tetramethylammonium hydroxide (TMAH) or potassium hydroxide (KOH) is used.

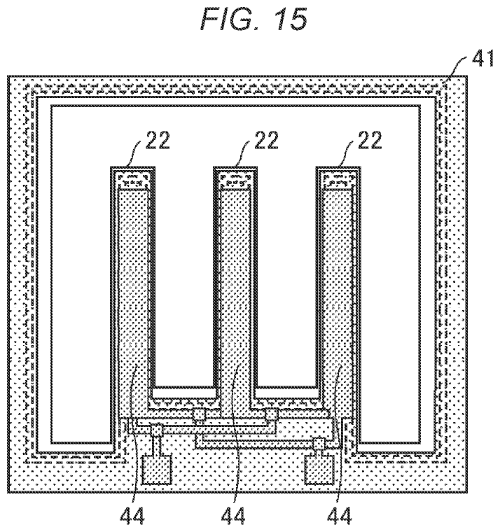

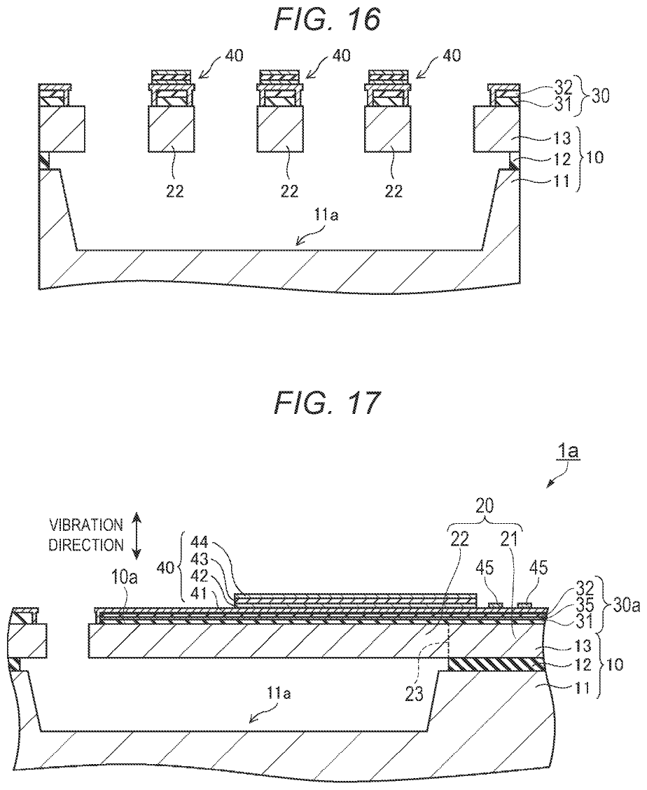

In an eighth process, as shown in FIGS. 15 and 16, the silicon dioxide layer 31, the silicon dioxide layer 33, and the buried oxide films 12 around the arms 22 and the piezoelectric drive unit 40 are release-etched. Accordingly, the temperature coefficient adjusting film 30 having a stacked structure of the silicon dioxide layer 31 and the zirconium dioxide layer 32 remains only on the arms 22. In the eighth process, wet etching is performed, and as an etching solution, for example, buffered hydrofluoric acid (BHF) is used. As a result, the vibrator element 1 as shown in FIGS. 1 to 3 can be obtained.

### 2. Second Embodiment

Next, a vibration piece 1a according to a second embodiment will be described with reference to FIG. 17. The same reference numerals are given to configurations the same as those of the first embodiment described above, and the description thereof will be omitted.

The vibrator element 1a of the second embodiment is the same as the vibrator element 1 of the first embodiment except that a configuration of a temperature coefficient adjusting film 30a is different from that of the vibrator element 1 of the first embodiment.

In the vibrator element 1a, as shown in FIG. 17, an aluminum oxide (Al₂O₃) layer 35 is arranged between the silicon dioxide layer 31 and the zirconium dioxide layer 32 of the temperature coefficient adjusting film 30a arranged on the main surface 10a of the surface silicon layer 13 which is the vibrating body 20. That is, the temperature coefficient adjusting film 30a has a three-layer structure in which the silicon dioxide layer 31, the aluminum oxide layer 35, and the zirconium dioxide layer 32 are stacked in this order.

The aluminum oxide layer 35 is accurately formed by using, for example, a sputtering technique, a photolithography technique, an etching technique, or the like. A thickness of the aluminum oxide layer 35 is preferably 0.01 μm or more and 0.3 μm or less.

With such a configuration, the adhesion between the silicon dioxide layer 31 and the zirconium dioxide layer 32 can be improved, and a vibrator element 1a having higher reliability can be obtained.

### 3. Third Embodiment

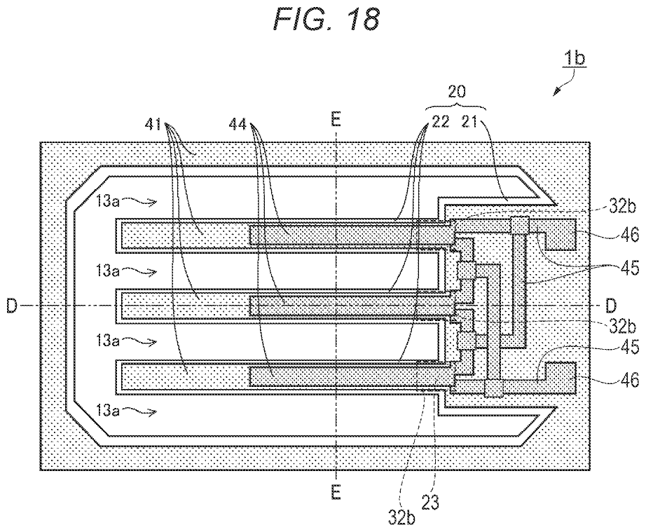

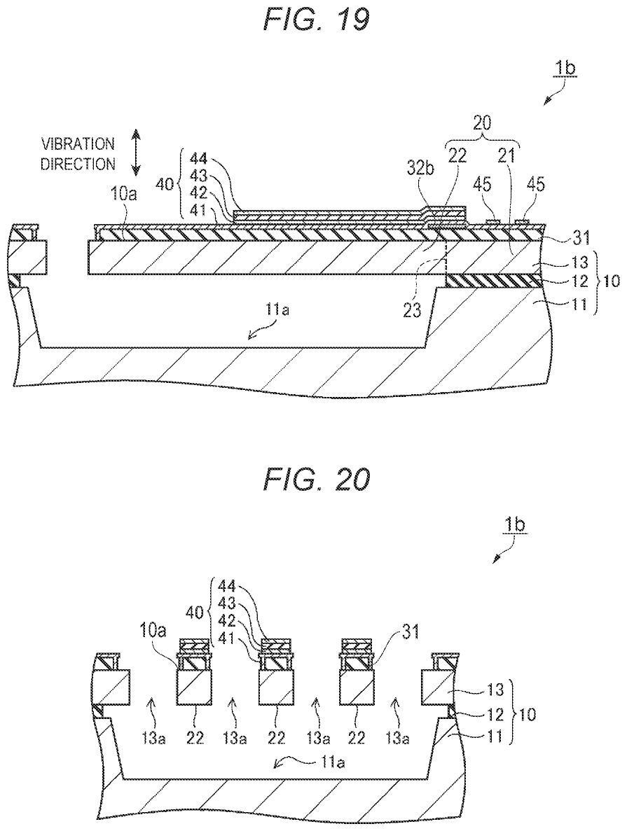

Next, a vibration piece 1b according to a third embodiment will be described with reference to FIGS. 18, 19 and 20. The same reference numerals are given to the configurations the same as those of the first embodiment described above, and the description thereof will be omitted.

The vibrator element 1b of the third embodiment is the same as the vibrator element 1 of the first embodiment except that an arrangement position of a zirconium dioxide layer 32b is different from that of the vibrator element 1 of the first embodiment.

In the vibrator element 1b, as shown in FIGS. 18, 19, and 20, the zirconium dioxide layer 32b is arranged only in the continuous portion 23 in which the arms 22 and the base 21 are continuous. More specifically, the zirconium dioxide layer 32b is arranged in a position continuous with the continuous portion 23 in which the arms 22 and the base 21 are continuous, a part of the arms 22 coupled to the continuous portion 23, and a part of the base 21 coupled to the continuous portion 23.

With such a configuration, the bending strength of the continuous portion 23 in which the arms 22 and the base 21 are continuous in the vibration direction can be increased with the stress repeatedly concentrated in the continuous portion 23 due to the vibration of the vibrating body 20, and a vibrator element 1b having a high reliability can be obtained.

What is claimed is:

1. A vibrator element, comprising:
a base;
an arm that is made of silicon and continuous with the base;
a silicon dioxide layer arranged on the arm and a continuous portion in which the arm and the base are continuous;
a zirconium dioxide layer arranged on the silicon dioxide layer at least in the continuous portion;
a first electrode arranged on the zirconium dioxide layer;
a piezoelectric layer arranged on the first electrode; and
a second electrode arranged on the piezoelectric layer.

2. The vibrator element according to claim 1, wherein
a thickness of the silicon dioxide layer is larger than a thickness of the zirconium dioxide layer.

3. The vibrator element according to claim 1, wherein
a thickness of the zirconium dioxide layer is 0.4 μm or more and 1.0 μm or less.

4. The vibrator element according to claim 1, further comprising:
an aluminum oxide layer arranged between the silicon dioxide layer and the zirconium dioxide layer.

5. The vibrator element according to claim 1, wherein
the piezoelectric layer is aluminum nitride.

6. The vibrator element according to claim 1, wherein
the zirconium dioxide layer is arranged on the arm and the continuous portion.

7. The vibrator element according to claim 1, wherein
the zirconium dioxide layer is arranged only on the continuous portion.
